(19) United States
(12) Patent Application Publication
(10) Pub. No.: US 2014/0077324 A1
(43) Pub. Date: Mar. 20, 2014

(54) SOLID-STATE IMAGE PICKUP DEVICE, METHOD OF MANUFACTURING SOLID-STATE IMAGE PICKUP DEVICE, AND ELECTRONIC APPARATUS

(71) Applicant: SONY CORPORATION, TOKYO (JP)

(72) Inventor: Hiroyasu Matsugai, Kanagawa (JP)

(73) Assignee: SONY CORPORATION, TOKYO (JP)

(21) Appl. No.: 14/026,624

(22) Filed: Sep. 13, 2013

(30) Foreign Application Priority Data
Sep. 20, 2012 (JP) 201206569
Nov. 27, 2012 (JP) 2012258402

(51) Int. Cl. H01L 31/0232

(52) U.S. Cl. CPC H01L 31/02325
USPC 257/432; 438/29

(57) ABSTRACT

A solid-state image pickup device includes: a plurality of pixels each including an organic photoelectric conversion layer; a sealing layer that covers the pixels; and a first lens section provided for each of the pixels and provided on a side, of the sealing layer, on which the organic photoelectric conversion layer is located. The first lens section is formed integrally with the sealing layer.

### BACKGROUND

The present disclosure relates to a solid-state image pickup device that includes a photoelectric conversion element as a pixel, a method of manufacturing such a solid-state image pickup device, and an electronic apparatus.

For solid-state image pickup devices, including charge coupled device (CCD) and complementary metal oxide semiconductor (CMOS) image sensors, a structure is proposed in which three color signals are acquired from a single pixel containing stacked photoelectric conversion layers for plural colors (for example, R, G, and B) (for example, see Japanese Unexamined Patent Application Publication No. 2011-29337). In the solid-state image pickup device as described in this document, for example, an organic photoelectric conversion section is provided on a silicon substrate and photodiodes (inorganic photoelectric conversion sections) are provided therein. Further, the organic photoelectric conversion section detects green light to generate signal charges in accordance with the detected green light, and the photodiodes detect red light and blue light, respectively.

### SUMMARY

For the solid-state image pickup device as described above, a structure is in demand which makes it possible to enhance an efficiency of collecting light to the organic photoelectric conversion layer without lowering its own reliability due to the deterioration of the organic photoelectric conversion material.

It is desirable to provide a solid-state image pickup device that is capable of enhancing an efficiency of collecting light to an organic photoelectric conversion layer while securing reliability, a method of manufacturing such a solid-state image pickup device, and an electronic apparatus.

A solid-state image pickup device according to an embodiment of the present disclosure includes: a plurality of pixels each including an organic photoelectric conversion layer; a sealing layer that covers the pixels; and a first lens section provided for each of the pixels and provided on a side, of the sealing layer, on which the organic photoelectric conversion layer is located. The first lens section is formed integrally with the sealing layer.

A method of manufacturing a solid-state image pickup device according to an embodiment of the present disclosure includes: forming a plurality of pixels each including an organic photoelectric conversion layer; and forming a sealing layer that covers the pixels, the forming the sealing layer including forming a first lens section provided for each of the pixels and provided on a side, of the sealing layer, on which the organic photoelectric conversion layer is located. The first lens section is formed integrally with the sealing layer.

An electronic apparatus according to an embodiment of the present disclosure is provided with a solid-state image pickup device that includes: a plurality of pixels each including an organic photoelectric conversion layer; a sealing layer that covers the pixels; and a first lens section provided for each of the pixels and provided on a side, of the sealing layer, on which the organic photoelectric conversion layer is located. The first lens section is formed integrally with the sealing layer.

In the solid-state image pickup device, the method of manufacturing the solid-state image pickup device, and the electronic apparatus, according to the above-described embodiments of the present disclosure, the first lens section is provided integrally with the sealing layer on the organic photoelectric conversion layer side of the sealing layer. With this configuration, damage to the organic photoelectric conversion layer is decreased during manufacturing processing, and the coverage of the sealing layer is enhanced.

According to the solid-state image pickup device, the method of manufacturing the solid-state image pickup device, and the electronic apparatus, according to the above-embodiment embodiments of the present disclosure, on the side on which the organic photoelectric conversion layer is located of the sealing layer, the first lens section is provided integrally with the sealing layer. Consequently, this configuration makes it possible to increase an efficiency of collecting light to the organic photoelectric conversion layer while securing reliability.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a cross-sectional view of an exemplary general configuration of a photoelectric conversion element (pixel) according to an embodiment of the present disclosure.

FIG. 2 is a cross-sectional view of a configuration of a main part of the photoelectric conversion element according to the embodiment of the present disclosure.

FIGS. 3A and 3B are cross-sectional views of an exemplary configuration of an inorganic photoelectric conversion section.

FIG. 4 is a cross-sectional view of an exemplary configuration of a charge (electron) storage layer in an organic photoelectric conversion section.

FIG. 5 is an enlarged view of a stack structure of the organic photoelectric conversion section of FIG. 2.

FIG. 6 is an explanatory cross-sectional view of a method of manufacturing the photoelectric conversion element of FIG. 1 or 2.

FIG. 7 is a cross-sectional view illustrating a processing step that follows FIG. 6.

FIGS. 8A and 8B are cross-sectional views illustrating processing steps that follow FIGS. 7 and 8A, respectively.

FIGS. 9A and 9B are cross-sectional views illustrating processing steps that follow.

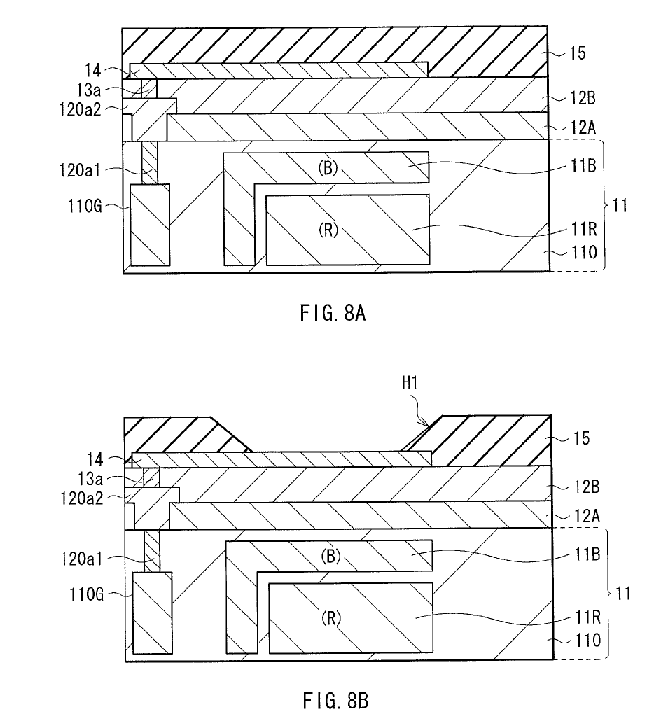

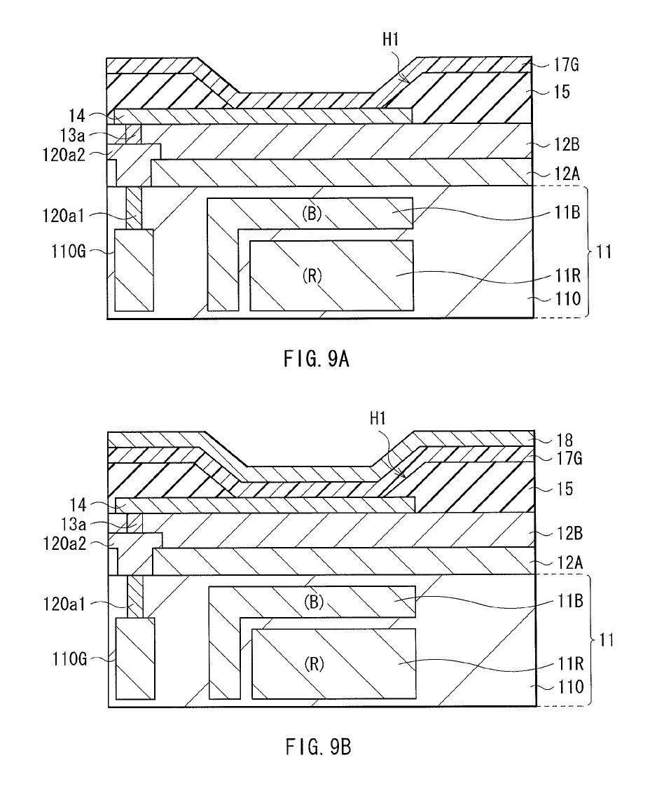

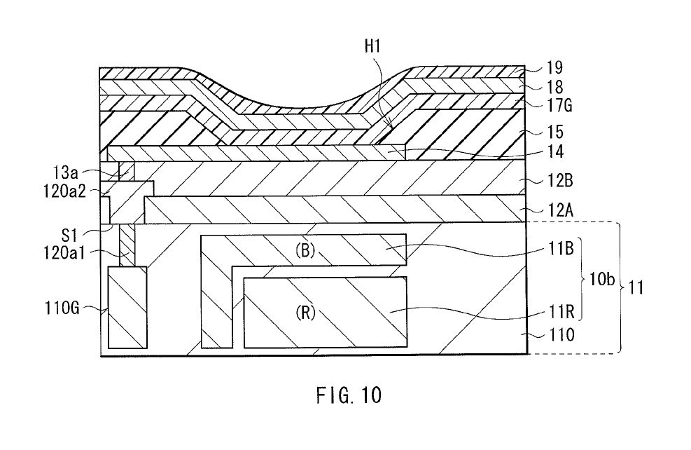

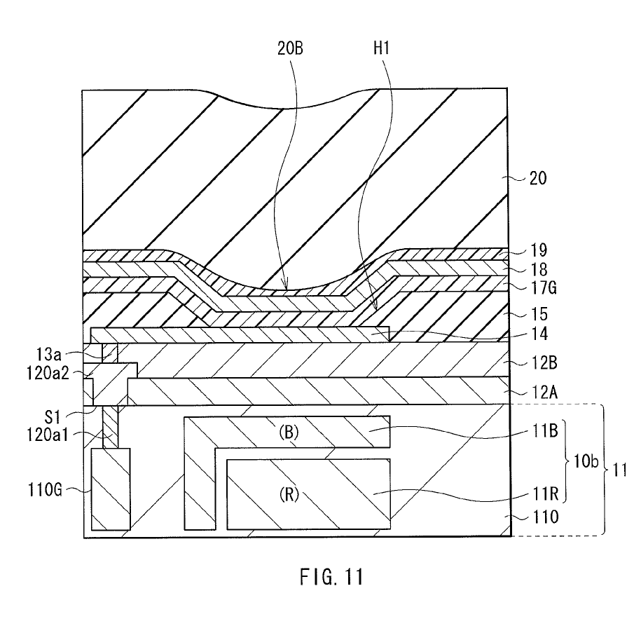

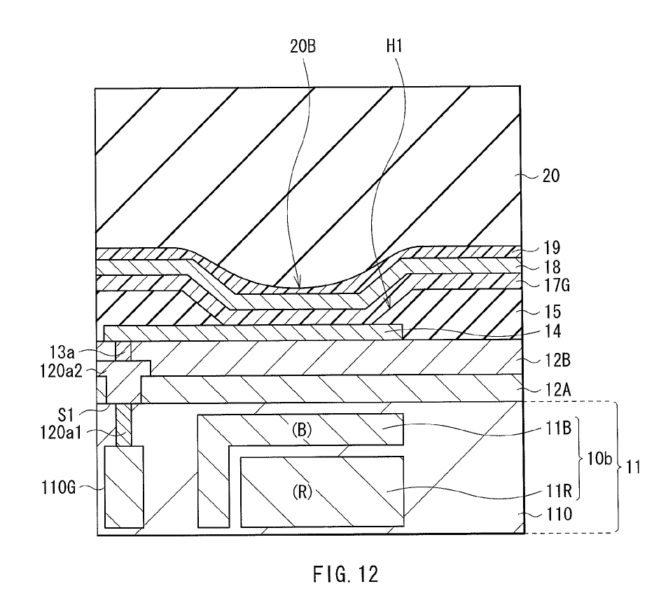

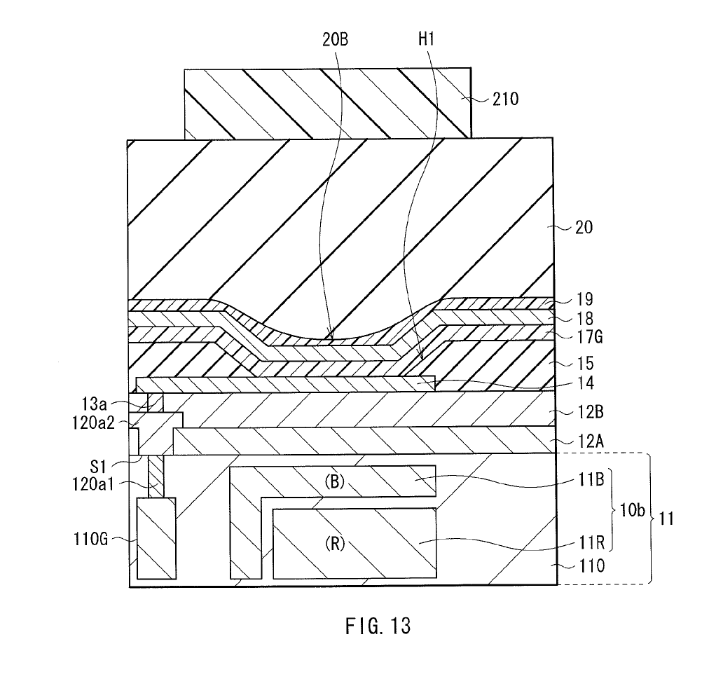

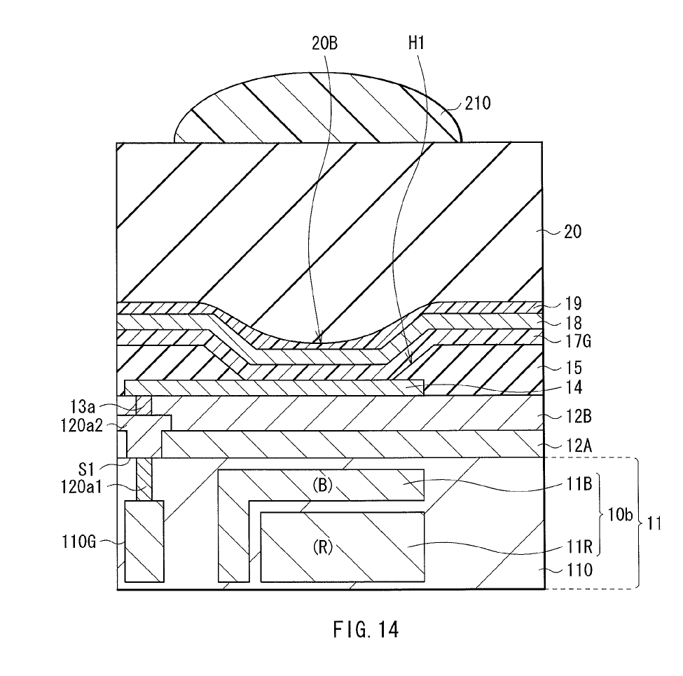

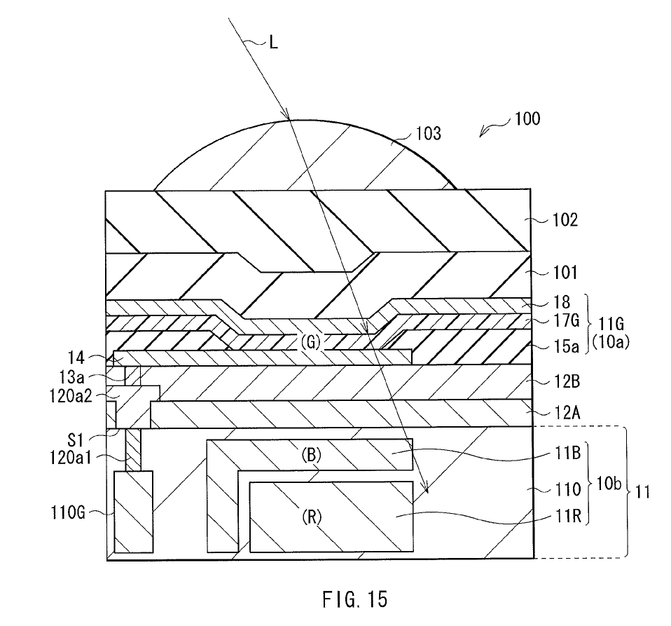

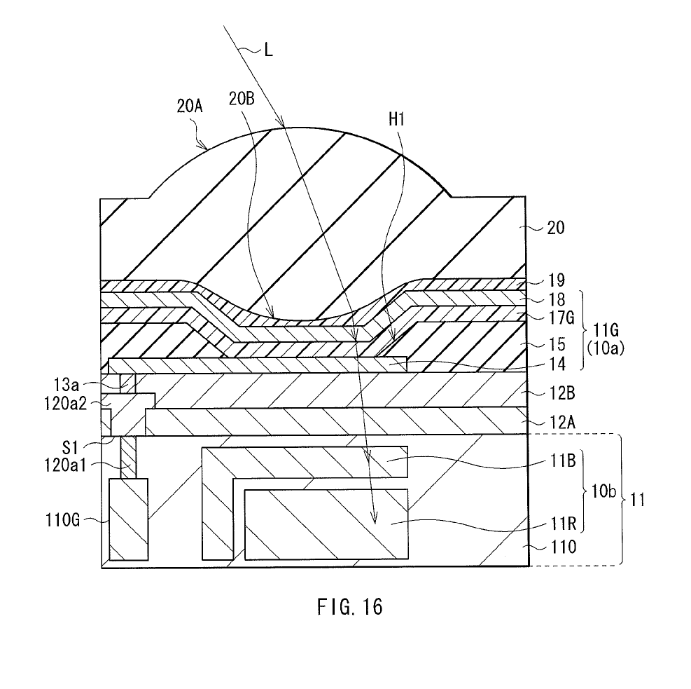

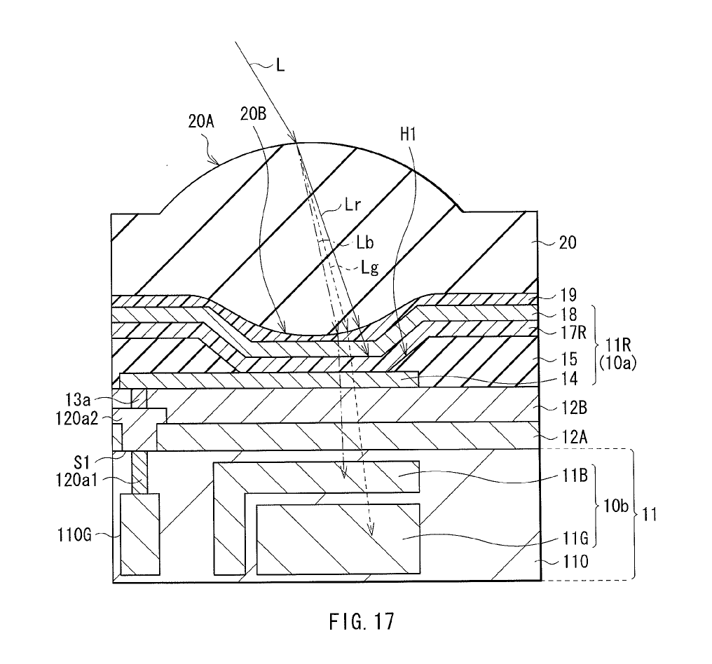

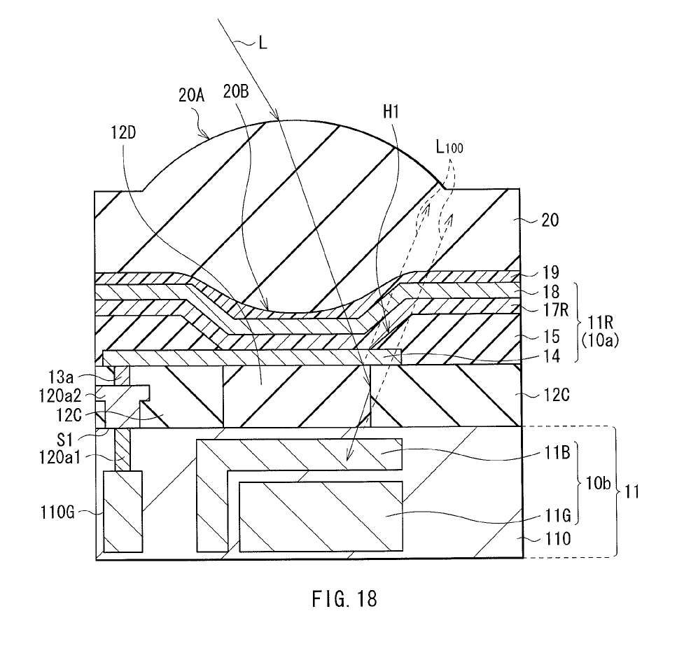

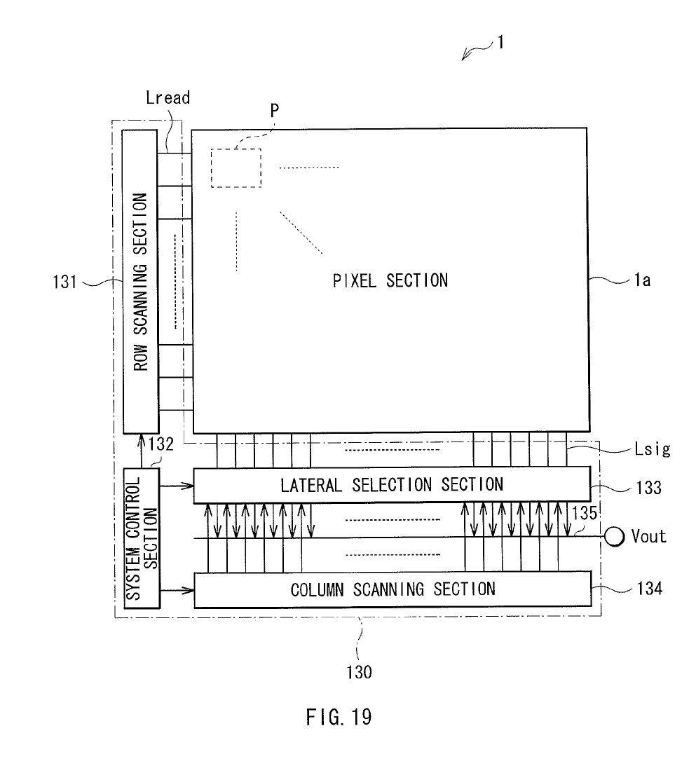

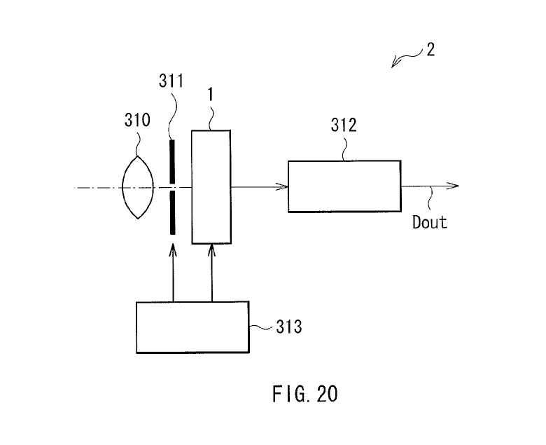

FIGS. 8B and 9A, respectively.

FIG. 10 is a cross-sectional view illustrating a processing step that follows FIG. 9B.

FIG. 11 is a cross-sectional view illustrating a processing step that follows FIG. 10.

FIG. 12 is a cross-sectional view illustrating a processing step that follows FIG. 11.

FIG. 13 is a cross-sectional view illustrating a processing step that follows FIG. 12.

FIG. 14 is a cross-sectional view illustrating a processing step that follows FIG. 13.

FIG. 15 is an explanatory, schematic cross-sectional view of a light collection efficiency of a photoelectric conversion element according to a comparative example.

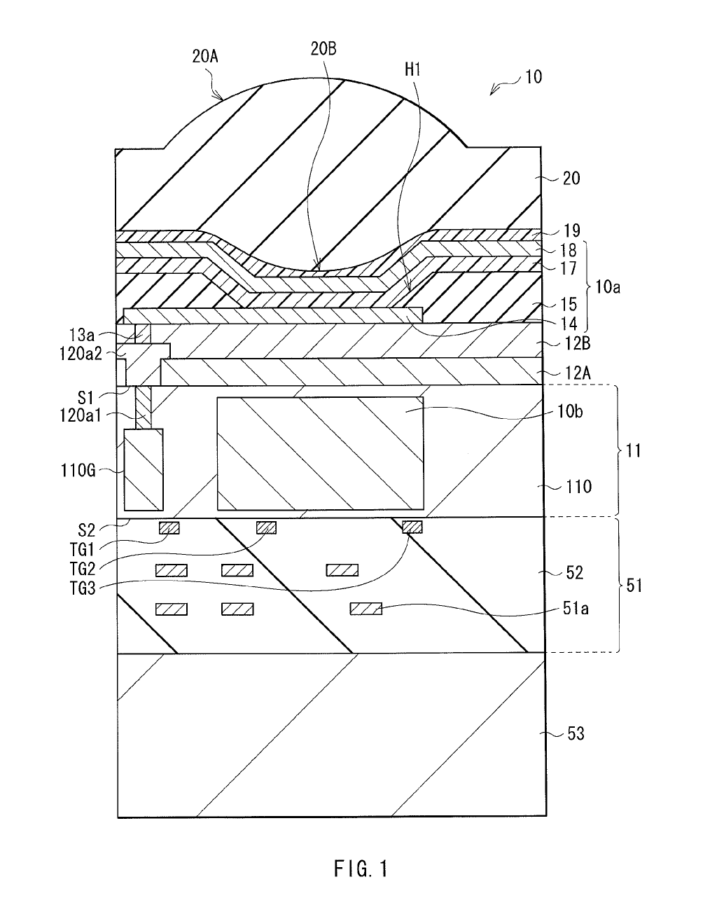

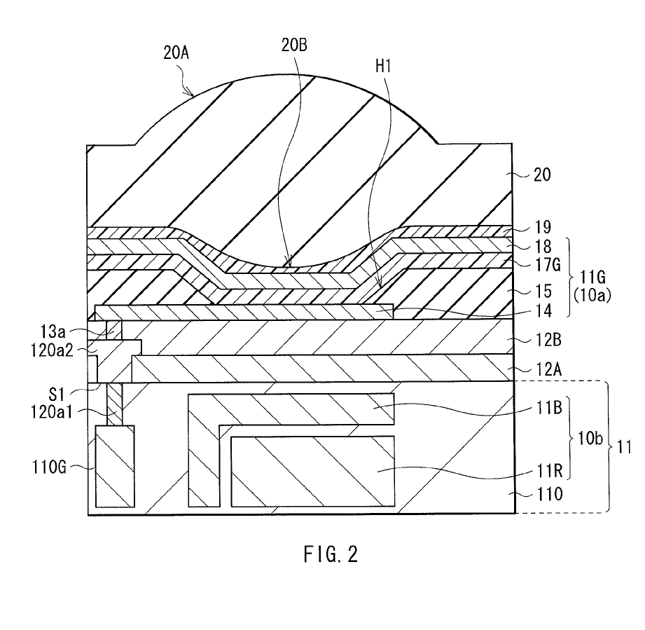

FIG. 16 is an explanatory, schematic cross-sectional view of a light collection efficiency of the photoelectric conversion element of FIG. 1 or 2.

FIG. 17 is a cross-sectional view of a configuration of a main part of a photoelectric conversion element (pixel) according to modification 1.

FIG. 18 is a cross-sectional view of a configuration of a main part of a photoelectric conversion element (pixel) according to modification 3.

FIG. 19 is a functional block diagram illustrating a solid-state image pickup device.

FIG. 20 is a functional block diagram illustrating an electronic apparatus according to an exemplary application.

### DETAILED DESCRIPTION

Hereinafter, an embodiment and the like of the present disclosure will be described in detail, with reference to the accompanying drawings. The description will be given in the following order.

1. Embodiment (an example of a photoelectric conversion element in which a lower convex lens section is formed integrally with a sealing layer)
2. Modification 1 (an example of a case where a design is produced in consideration of a relationship between a received light wavelength and a refractive index)
3. Modification 2 (an example of a case where pupil correction is made)
4. An exemplary overall configuration of a solid-state image pickup device
5. Exemplary application (an example of an electronic apparatus (camera))

### Embodiment

### Configuration

FIG. 1 illustrates a general configuration of a cross-section of a pixel (photoelectric conversion element 10) in a solid-state image pickup device according to an embodiment of the present disclosure. The solid-state image pickup device may serve as, for example, a charge coupled device (CCD) or complementary metal oxide semiconductor (CMOS) image sensor, and a detail thereof will be described later. In the photoelectric conversion element 10, pixel transistors (including transfer transistors Tr1 to Tr3 to be described later) are formed on a front surface (or a surface S2 located on the opposite side of a light receiving surface) of a semiconductor substrate, and a multilayer wiring layer (multilayer wiring layer 51) is provided thereon.

The photoelectric conversion element 10 may have a structure, for example, in which an organic photoelectric conversion section 10a and an inorganic photoelectric conversion section 10b are stacked vertically. Further, the organic photoelectric conversion section 10a and the inorganic photoelectric conversion section 10b selectively detect light of different wavelengths to photoelectrically convert the light. The organic photoelectric conversion section 10a is formed on a semiconductor substrate 11, and includes an organic photoelectric conversion layer (organic photoelectric conversion layer 17). Meanwhile, the inorganic photoelectric conversion section 10b is formed in the semiconductor substrate 11. Because of this structure, the solid-state image pickup device to be described later acquires multi-colored signals from each pixel without using a color filter.

In this embodiment, as illustrated in FIG. 2, the photoelectric conversion element 10 has a structure in which a single organic photoelectric conversion section 11G and two inorganic photoelectric conversion layers 11B and 11R are stacked vertically. With this structure, color signals of red (R), green (G), and blue (B) are acquired. The organic photoelectric conversion section 11G is provided with an organic photoelectric conversion layer 17G that may detect, for example, green light (namely, photoelectrically converts the green light). The inorganic photoelectric conversion section 10b is provided with the inorganic photoelectric conversion layers 11B and 11R that may detect, for example, blue light and red light, respectively.

### (Semiconductor Substrate 11)

The semiconductor substrate 11 may have a structure, for example, in which the inorganic photoelectric conversion layers 11B and 11R and a green storage layer 110G are embedded in respective predetermined regions of an n-type silicon (Si) layer 110. In addition, a conductive plug 120a1 is also embedded in the semiconductor substrate 11. The conductive plug 120a1 creates a transmission path for electric charges (electrons or holes) transmitted from the organic photoelectric conversion section 11G. In this embodiment, the back surface (surface 51) of the semiconductor substrate 11 serves as the light receiving surface. In addition, the plurality of pixel transistors (including the transfer transistors Tr1 to Tr3) and a peripheral circuit including a logic circuit are formed on the front surface (surface S2) of the semiconductor substrate 11. The pixel transistors correspond to the organic photoelectric conversion section 11G and the inorganic photoelectric conversion layers 11B and 11R, respectively.

Examples of each pixel transistor may include a transfer transistor, a reset transistor, an amplifier transistor, and a selection transistor. Each pixel transistor, as described above, may be configured of, for example, an MOS transistor, and formed in a p-type semiconductor well region on the surface S2. Circuits including the pixel transistors are formed corresponding to the photoelectric conversion sections for red, green, and blue. Each circuit may employ, for example, a three-transistor configuration including the transfer transistor, the reset transistor, and the amplifier transistor out of the above pixel transistors, or a four-transistor configuration including the selection transistor in addition to those three transistors. Here, out of the above pixel transistors, only the transfer transistors Tr1 to Tr3 are illustrated. Specifically, only respective gate electrodes (gate electrodes TG1 to TG3) of the transfer transistors Tr1 to Tr3 are illustrated in FIG. 1. Each of the pixel transistors other than the transfer transistors may be shared by the multiple photoelectric conversion sections or pixels. Moreover, a structure in which a floating diffusion is shared, or so-called a pixel sharing structure, may be applicable.

Each of the transfer transistors Tr1 to Tr3 includes a gate electrode (gate electrode TG1, TG2, or TG3) and a floating diffusion (FD113, FD114, or FD116). The transfer transistor Tr1 transfers signal charges (electrons in this embodiment) corresponding to a green color, which have been generated in the organic photoelectric conversion section 11G and stored in the green storage layer 110G, to a vertical signal line Lsig to be described later. The transfer transistor Tr2 transfers signal charges (electrons in this embodiment) corresponding to a blue color, which have been generated and stored in the inorganic photoelectric conversion layer 11B, to the vertical signal line Lsig to be described later. Likewise, the transfer transistor Tr3 transfers signal charges (electrons in this embodiment) corresponding to a red color, which have been generated and stored in the inorganic photoelectric conversion layer 11R, to the vertical signal line Lsig to be described later.

Each of the inorganic photoelectric conversion layers 11B and 11R is a photodiode having a pn junction. For example, the inorganic photoelectric conversion layers 11B and 11R may be formed in the semiconductor substrate 11 in this order from the side of the surface S1 (light incident side). Out of these layers, the inorganic photoelectric conversion layer 11B selectively detects blue light and stores signal charges corresponding to the blue color. For example, the inorganic photoelectric conversion layer 11B may be formed so as to extend from a selective region along the surface S1 of the semiconductor substrate 11 to a region in the vicinity of an interface with the multilayer wiring layer 51. Meanwhile, the inorganic photoelectric conversion layer 11R selectively detects red light and stores signal charges corresponding to the red color. For example, the inorganic photoelectric conversion layer 11R may be formed in an under-layer region relative to the inorganic photoelectric conversion layer 11B (on the surface S2 side). Note that the blue (B) and red (R) may correspond to, for example, light with a wavelength range from 450 nm to 495 nm and light with a wavelength range from 620 nm to 750 nm, respectively. It is only necessary for each of the inorganic photoelectric conversion layers 11B and 11R to detect light that partially or entirely covers the corresponding wavelength range.

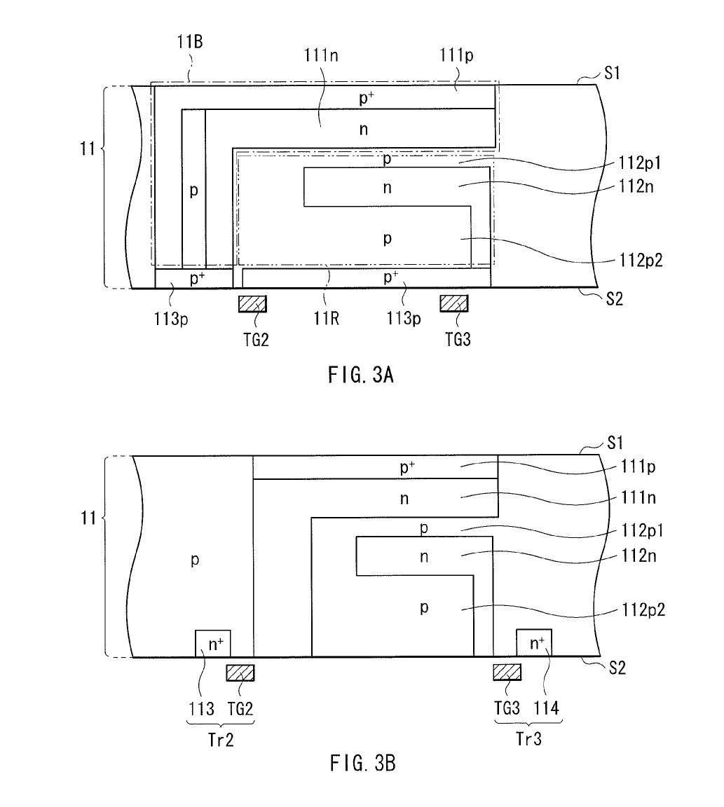

FIGS. 3A and 3B each illustrate an exemplary detailed configuration of the inorganic photoelectric conversion layers 11B and 11R. In FIGS. 3A and 3B, the different cross-sectional configurations are illustrated. Note that in this embodiment, a description will be given regarding a case where out of pairs of electron and hole generated as a result of the photoelectric conversion, the electrons are read as signal charges (or a case where an n-type semiconductor region is used as the photoelectric conversion layer). In each of FIGS. 3A and 3B, a superscript “+” for “p” or “n” denotes a p-type or n-type of high impurity concentration. Furthermore, the gate electrodes TG2 and TG3 of the transfer transistors Tr2 and Tr3, respectively, out of the pixel transistors are also illustrated in each of FIGS. 3A and 3B.

The inorganic photoelectric conversion layer 11B includes: for example, a p-type semiconductor region 111p (hereinafter, simply referred to as a p-type region, and this also applies to a case where the semiconductor region 111p has an n-type) which serves as a hole storage layer; and an n-type photoelectric conversion layer 111n (n-type region) which serves as an electron storage layer. The p-type region 111p and the n-type photoelectric conversion layer 111n are formed in respective selective regions close to the surface S1, and each of them is formed such that it is partially bent and the pent part extends to the interface with the surface S2. The p-type region 111p is connected to the p-type semiconductor well region (not illustrated) on the surface S1. Meanwhile, the n-type photoelectric conversion layer 111n is connected to the FD113 (n-type region) of the transfer transistor Tr2 for the blue color. Furthermore, a p-type region 113p (hole storage layer) is formed in the vicinity of an interface between the surface S2 and an end of each of the p-type region 111p and the n-type photoelectric conversion layer 111n which are on the surface S2 side.

The inorganic photoelectric conversion layer 11R may be formed, for example, by sandwiching an n-type photoelectric conversion layer 112n (electron storage layer) between p-type regions 112p1 and 112p2 (hole storage layers) (namely, has a p-n-p stack structure). The n-type photoelectric conversion layer 112n is formed such that it is partially bent and the bent part extends to the interface of the surface S. The n-type photoelectric conversion layer 112n is connected to the FD 114 (n-type region) of the red transfer transistor Tr3. Moreover, another p-type region 113p (hole storage layer) is formed at least in the vicinity of an interface between the surface S2 and an end of the n-type photoelectric conversion layer 112n on the surface S2 side.

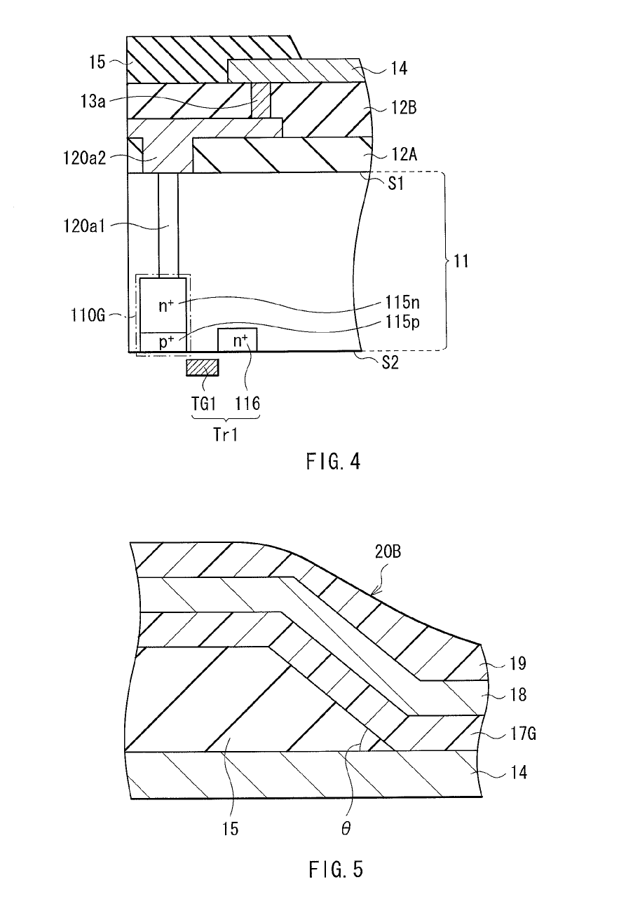

FIG. 4 illustrates an exemplary detailed configuration of the green storage layer 110G. Herein, a description will be given regarding a case where out of couples of electron and hole generated in the organic photoelectric conversion section 11G, electrons are read from a lower electrode 14 as signal charges. In FIG. 4, the gate electrode TG1 of the transfer transistor Tr1, out of the pixel transistors, are also illustrated.

The green storage layer 110G includes an n-type region 115n that serves as the electron storage layer. Part of the n-type region 115n is connected to the conductive plug 120a1, and stores electrons supplied from the lower electrode 14 through the conductive plug 120a1. The n-type region 115n is also connected to the FD116 (n-type region) of the transfer transistor Tr1 for the green color. Furthermore, a p-type region 115p (hole storage layer) is formed in the vicinity of an interface between the n-type region 115n and the surface S2.

The conductive plug 120a1 serves as a connector that connects the organic photoelectric conversion section 11G and the semiconductor substrate 11, in conjunction with a conductive plug 120a2 to be described later, and creates a transmission path for electrons or holes generated in the organic photoelectric conversion section 11G. In this case, the conductive plug 120a1 establishes electrical continuity with the lower electrode 14 of the organic photoelectric conversion section 11G, and is connected to the green storage layer 110G.

The conductive plug 120a1, as described above, may be configured of, for example, a conductive semiconductor layer, and is formed and embedded in the semiconductor substrate 11. In this case, it is preferable for the conductive plug 120a1 to have an n-type, in order to serve as the transmission path for electrons. Alternatively, the conductive plug 120a1 may have a structure, for example, in which a conductive film material made of tungsten or the like is filled in a via hole. In this case, it is desirable for the side surface of the via hole to be covered by an insulating film made of, for example, silicon oxide (SiO₂) or silicon nitride (SiN), for the purpose of avoiding a short-circuit between the conductive film material and the silicon.

A support substrate 53 made of, for example, silicon is bonded to the surface S2 of the semiconductor substrate 11, as described above, through the multilayer wiring layer 51. In the multilayer wiring layer 51, a plurality of wires 51a are disposed through an interlayer insulating film 52. In the photoelectric conversion element 10, the multilayer wiring layer 51 is formed on the opposite side of the light receiving surface, as described above. Therefore, the photoelectric conversion element 10 is configured to be able to realize so-called a backside illumination type of solid-state image pickup device.

### (Organic Photoelectric Conversion Section)

The organic photoelectric conversion section 10a (in this case, the organic photoelectric conversion section 11G) is an organic photoelectric conversion element that uses an organic semiconductor to absorb light of a selective wavelength (here, green light), generating couples of electron and hole. The organic photoelectric conversion section 10a (11G) has a configuration in which the organic photoelectric conversion layer 17 (17G) is sandwiched between a pair of electrodes (or the lower electrode 14 and an upper electrode 18) from which signal charges are to be extracted. The lower electrode 14 (first electrode) is electrically connected to the conductive plug 120a1 embedded in the semiconductor substrate 11. Meanwhile, the upper electrode 18 (second electrode) is connected to the wire 51a in the multilayer wiring layer 51 through a contact portion (not illustrated), for example, in an outer rim portion of the solid-state image pickup device. With this configuration, the electric charges (here, holes) are discharged.

The organic photoelectric conversion section 11G is formed on the surface S1 of the semiconductor substrate 11 through interlayer insulating films 12A and 12B. The conductive plug 120a2 is embedded in a region of the interlayer insulating film 12A which opposes the conductive plug 120a1, and a wire layer 13a is embedded in a region of the interlayer insulating film 12B which opposes the conductive plug 120a2. The lower electrode 14 is disposed on the interlayer insulating film 12B, and an insulating film 15 having an aperture H1 is provided on the lower electrode 14.

The organic photoelectric conversion layer 17G and the upper electrode 18 are provided on the insulating film 15 in this order. The surface of the lower electrode 14 is exposed above the aperture H1 of the insulating film 15, and the organic photoelectric conversion layer 17G makes contact with the lower electrode 14 within the aperture H1. In the case where the signal charges are extracted from the lower electrode 14 as in this embodiment, the lower electrode 14 is provided for each pixel, and the individual lower electrodes 14 are electrically separated from one another by the insulating film 15. As described above, the organic photoelectric conversion layer 17G and the upper electrode 18 are formed on the lower electrode 14 through the insulating film 15. Accordingly, each of the organic photoelectric conversion layer 17G and the upper electrode 18 has a recess formed corresponding to the aperture H1 of the insulating film 15. In other words, an upper surface (light incident surface) of each of the organic photoelectric conversion layer 17G and the upper electrode 18 is formed so as to conform to an uneven shape (steps created by the aperture H1) of the insulating film 15 (or reflects the uneven shape of the insulating film 15). Furthermore, an application film 19 is provided on the upper electrode 18, and a sealing layer 20 is formed adjacent to the application film 19. A concrete configuration of the sealing layer 20 will be described later.

The conductive plug 120a2 functions as a connector together with the conductive plug 120a1, as described above, and creates a transmission path for electric charges (electrons) which extends from the lower electrode 14 to the green storage layer 110G in conjunction with the conductive plug 120a1 and the wire layer 13a. The conductive plug 120a2 may also function as a light shielding film. In this case, it is desirable for the conductive plug 120a2 to be configured of a stacked-layer film made of metallic materials, including titanium (Ti), titanium nitride (TiN), and tungsten.

It is desirable for the interlayer insulating film 12A to be configured of an insulating film having a low interface state, in order to reduce the interface state with the semiconductor substrate 11 (silicon layer 110) and prevent a dark current from being generated at the interface with the silicon layer 110. For the insulating film as described above, for example, a stacked-layer film including, for example, a hafnium oxide (HfO₂) film and a silicon oxide (SiO₂) film may be used. The interlayer insulating film 12B may be configured of a single-layer film made of, for example, one of silicon oxide, silicon nitride, and silicon oxynitride (SiON), or a stacked-layer film made of two or more of them.

The lower electrode 14 is provided in a region covering the respective light receiving surfaces of the inorganic photoelectric conversion layers 11B and 11R formed in the semiconductor substrate 11, so as to oppose the light receiving surfaces. The lower electrode 14 exhibits a light transmitting property, and may be made of a conductive film having a refractive index of, for example, approximately 1.8 to 2.0, such as indium tin oxide (ITO) film. In addition, tin oxide (TO), a tin oxide (SnO₂) based material formed by adding a dopant to tin oxide, or a zinc oxide (ZnO) based material formed by adding a dopant to zinc oxide may also be used. Examples of the zinc oxide based material include aluminum zinc oxide (AZO) formed by adding aluminum (Al) as a dopant, gallium zinc oxide (GZO) formed by adding gallium (Ga) as a dopant, and indium zinc oxide (IZO) formed by adding indium (In) as a dopant. In addition, CuI, InSbO₄, ZnMgO, CuInO₂, MgIN₂O₄, CdO, ZnSnO₃, or the like may be used. As described above, the signal charges (electrons) are extracted from the lower electrode 14 in this embodiment. Therefore, in a solid-state image pickup device to be described later in which the photoelectric conversion element 10 is used as each pixel, the lower electrodes 14 are separated from one another by the insulating film 15 so as to correspond to the individual pixels.

The insulating film 15 may be configured of a single-layer film made of, for example, one of silicon oxide, silicon nitride, and silicon oxynitride (SiON), or a stacked-layer film made of two or more of them. The insulating film 15 has a function of electrically separating the lower electrodes 14 from one another, so as to correspond to the individual pixels, when the photoelectric conversion element 10 is used as each pixel of the solid-state image pickup device. Furthermore, the insulating film 15 is tapered in the rim portion of the aperture H1. A tapered angle of this portion (tapered angle θ to be described later) may be set as appropriate, in accordance with the necessary curvature of the lower convex lens 20B in the sealing layer 20, as will be described later. It is desirable for the tapered angle θ to be 30 degrees or lower, as an example.

The organic photoelectric conversion layer 17 includes an organic semiconductor that absorbs light of a selective wavelength range to photoelectrically convert it and in turn allows light of another wavelength range to pass therethrough. It is desirable for this organic semiconductor to include one or both of p-type and n-type organic semiconductors. For the organic semiconductor, for example, one of quinacridon, naphthalene, anthracene, phenanthrene, tetracene, pyrene, perylene, and fluoranthene derivatives may be used as appropriate. Alternatively, a polymer of, for example, phenylenevinylene, fluorine, carbazole, indole, pyrene, pyrrole, picoline, thiophene, acetylene, or diacetylene, or a derivative thereof may also be used. Moreover, a metal complex dye, a rhodamine-based dye, a cyanine-based dye, a merocyanine-based dye, a phenylxanthene-based dye, a triphenylmethane-based dye, a rhodacyanine-based dye, a xanthene-based dye, a macrocyclic azaazulene-based dye, an azulene-based dye, naphthoquinone, an anthraquinone-based dye, a chain compound formed by condensing macrocyclic polycyclic aromatic compound, such as anthracene or pyrene, and aromatic or heterocyclic compound, a di-nitrogen-containing heterocyclic compound, such as quinolone, benzothiazole, or benzoxazole having squarylium and chlochonic groups as bonded chains, or a cyanine-like dye in which the squarylium and chlochonic groups are bonded may be used as appropriate. It is preferable for the above metal complex dye to be a dithiol metal complex dye, metal phthalocyanine dye, metal porphyrin dye, or ruthenium complex dye. However, there is no limitation on the metal complex dye. In this embodiment, the organic photoelectric conversion layer 17G has an ability to photoelectrically convert green light that partially or entirely cover a wavelength range, for example, from 495 nm to 570 nm, and is configured of one or more of the above materials. In addition, the organic photoelectric conversion layer 17G, as configured above, may be 50 nm to 500 nm thick, for example.

For the organic photoelectric conversion layer 17, an organic co-evaporated film, which is an organic semiconductor compound film formed by evaporating two or more types of organic semiconductors (for example, p-type and n-type organic semiconductors) at the same time, may be used. Furthermore, additional layers (not illustrated) may be provided between the organic photoelectric conversion layer 17 and the lower electrode 14 and between the organic photoelectric conversion layer 17 and the upper electrode 18. For example, an under-coated film, an electron blocking film, the organic photoelectric conversion layer 17, a hole blocking film, a buffer film, a work function adjusting layer, and the like may be stacked on the lower electrode 14, in this order.

The upper electrode 18 is configured of an inorganic conductive film that exhibits a light transmitting property, similar to the lower electrode 14. In the case where the signal charges are extracted from the lower electrode 14 as in this embodiment, the upper electrode 18 is provided so as to be shared by the multiple pixels.

The application film 19 may be made of, for example, a Low-k (low dielectric constant) material, such as spin on glass (SOG), a photoresist, or spin on dielectric (SOD), or an application type of material (that is capable of forming a film with an application method), such as polyimide or polybenzoxazole. Furthermore, it is desirable for the application film 19 to be made of a material having a lower refractive index than a material (inorganic material to be described later) of the sealing layer 20 has. With this configuration, a light collection efficiency of a lower convex lens portion 20B is increased. In this embodiment, the application film 19 is formed so as to cover the upper surface of the upper electrode 18, and the sealing layer 20 is provided adjacent to the upper surface of the application film 19. The thickness of the application film 19 may be set in accordance with the necessary curvature of the lower convex lens 20B in the sealing layer 20 as will be described later. This thickness may be approximately 100 nm, as an example.

The sealing layer 20 may be, for example, a single-layer film made of one of inorganic materials exhibiting light transmitting property, including a metal oxide and a metal nitride, such as a silicon oxide, silicon nitride, aluminum oxide, hafnium oxide, tantalum oxide, zirconium oxide, or titanium oxide, and a silicone resin, or a stacked-layer film made of two or more of them. However, there is no limitation on the material of the sealing layer 20. Alternatively, the sealing layer 20 may be a single-layer film made of, for example, an organic material exhibiting a light transmitting property, including polyimide, polybenzoxazole, an acrylic resin, and polystyrene, or a stacked-layer film made of two or more of them. Moreover, the sealing layer 20 may be formed by stacking inorganic and organic films made of the above materials. In this embodiment, an upper convex lens 20A and the lower convex lens 20B are provided integrally with the sealing layer 20 (or respective parts of the sealing layer 20 constitute the upper convex lens 20A and the lower convex lens 20B). The upper convex lens 20A corresponds to so-called an on-chip lens, and is formed on the upper surface of the sealing layer 20 (or a surface on the light incident side). Meanwhile, the lower convex lens 20B is formed on the lower surface of the sealing layer 20 (or a surface on the organic photoelectric conversion layer 17G side). In other words, the upper surface of the sealing layer 20 has a shape of a convex lens on the light incident side, whereas the lower surface thereof has a shape of a convex lens on the organic photoelectric conversion layer 17G side.

FIG. 5 illustrates part of the stacked layer structure of the organic photoelectric conversion section 11G in an enlarged fashion. The application film 19 is formed covering the upper electrode 18 having an uneven shape as described above, and the upper surface (light incident surface) of the application film 19 has a curved shape formed so as to substantially trace the upper surface of the upper electrode 18. Specifically, the upper surface of the application film 19 is formed of a smooth curved surface without any angled or warped portion, on the whole. Accordingly, the lower surface of the sealing layer 20 formed adjacent to the application film 19 (or the surface of the lower convex lens portion 20B) has a curved shape conforming to the curved shape of the application film 19. Here, the curved shape of the application film 19 is determined depending on design conditions, including the shape, size, and tapered angle θ of the aperture H1, the respective thicknesses of the insulating film 15, the organic photoelectric conversion layer 17, and the upper electrode 18, and the thickness and viscosity of the application film 19. Among those conditions, in particular, the thickness of the application film 19 enables the curved shape of the application film 19 to be controlled. Thus, controlling the thickness of the application film 19 makes it possible to provide the lower convex lens portion 20B with a desired surface shape (curvature).

The upper convex lens 20A and the lower convex lens 20B collect upwardly incident light to the respective light receiving surfaces of the organic photoelectric conversion layer 17G and the inorganic photoelectric conversion layers 11B and 11R. In this embodiment, the multilayer wiring layer 51 is formed on the surface S2 of the semiconductor substrate 11 (if the backside illumination type is employed). Accordingly, a distance decreases between the light receiving surfaces of the organic photoelectric conversion layer 17G and each of the inorganic photoelectric conversion layers 11B and 11R. This configuration successfully reduces the difference in response among the colors, depending on the F-number of the upper convex lens 20A. Furthermore, providing the lower convex lens 20B in addition to the upper convex lens 20A facilitates the increase in the light collection efficiency for each color light. The upper convex lens 20A and the lower convex lens 20B may have the same light collection point; however, it is desirable for their light collection points to be individually set in order to optimize the light collection efficiencies. For example, the upper convex lens 20A and the lower convex lens 20B may be designed, such that one of them has a light collection point optimized for the organic photoelectric conversion layer 17G, and the other has a light collection point optimized for the inorganic photoelectric conversion layers 11B and 11R. Moreover, as in a modification to be described later, a configuration in which the photoelectric conversion layers for the corresponding colors are stacked differently may be employed on the basis of a fact that the light collection point is dependent on a wavelength.

### (Manufacturing Method)

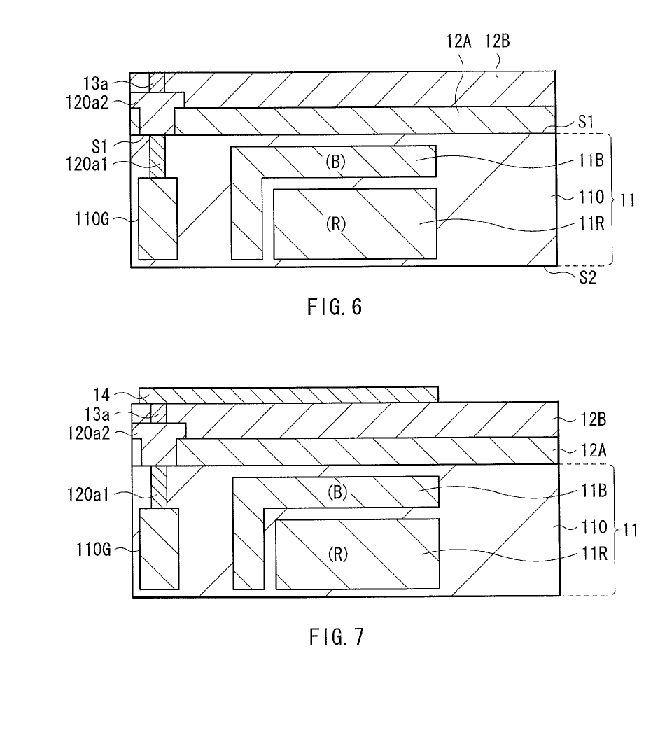

The photoelectric conversion element 10, as configured above, may be manufactured through the following exemplary processing steps. Each of FIGS. 6 to 14 depicts a method of manufacturing the photoelectric conversion element 10 in order of processing steps. However, only a configuration of a main part of the photoelectric conversion element 10 is illustrated, and a description will be given of processing steps through which the organic photoelectric conversion section 11G, the application film 19, and the sealing layer 20 are formed on the surface S1 of the semiconductor substrate 11.

Although not illustrated, before the formation of the organic photoelectric conversion section 11G, the semiconductor substrate 11 having the inorganic photoelectric conversion sections 11B and 11R is formed, and then the multilayer wiring layer 51 and the support substrate 53 are formed on the surface S2 of the semiconductor substrate 11, in advance. In more detail, first, a silicon layer 110 is formed on a temporary substrate made of, for example, a silicon oxide film, and then the semiconductor substrate 11 is formed by embedding the conductive plug 120a1, the green storage layer 110G, and the inorganic photoelectric conversion layers 11B and 11R in the silicon layer 110 with, for example, an ion injection. After that, the pixel transistors including the transfer transistors Tr1 to Tr3, the peripheral circuit including the logic circuit, and the multilayer wiring layer 51 are formed on the surface S2 of the semiconductor substrate 11. Followed by, after the support substrate 53 is bonded to the multilayer wiring layer 51, the above temporary substrate is removed from the surface S1 of the semiconductor substrate 11, so that the surface S1 of the semiconductor substrate 11 is exposed.

As illustrated in FIG. 6, the interlayer insulating films 12A and 12B are formed on the surface S1 of the semiconductor substrate 11, as a first processing step. In more detail, first, the interlayer insulating film 12A, which is formed of the stacked-layer film including a hafnium oxide film and a silicon oxide film as described above, is formed on the surface S1 of the semiconductor substrate 11. Specifically, after the hafnium oxide film is formed with, for example, an atomic layer deposition (ALD) method, the silicon oxide film is formed with, for example, a plasma CVD method. Then, a region of the interlayer insulating film 12A which opposes the conductive plug 120a1 is opened, and the conductive plug 120a2, which is made of the above material, is formed in the opening. Followed by, the interlayer insulating film 12B, which is made of the above material, is formed on the interlayer insulating film 12A with, for example, the plasma CVD method. Likewise, a region of the interlayer insulating film 12B which opposes the conductive plug 120a2 is opened, and the wire layer 13a, which is made of the above material, is formed in the opening.

Next, as illustrated in FIG. 7, the lower electrode 14 is formed on the interlayer insulating film 12B. In more detail, first, the above transparent conductive film is formed throughout the surface of the interlayer insulating film 12B. Examples of the method of forming this film include sol-gel, spin coating, spray, roll coating, ion beam deposition, electron beam deposition, laser ablation, CVD, and sputtering methods. Among the above methods, in particular, it is desirable for the sputtering method to be used in order to uniformly form the lower electrode 14 over a large area. Then, the lower electrode 14 is formed with, for example, patterning using dry (or wet) etching in a photolithography method. In this case, the lower electrode 14 is formed in a region that opposes the wire layer 13a, so that the lower electrode 14 is electrically connected to the green storage layer 110G through the wire layer 13a and the conductive plugs 120a1 and 120a2.

Next, as illustrated in FIG. 8A, the insulating film 15 is formed. In more detail, the insulating film 15, which is made of the above material, is formed above the overall surface of the semiconductor substrate 11 with, for example, the plasma CVD method, so as to cover the interlayer insulating film 12B and the lower electrode 14. Then, the surface of the formed insulating film 15 is planarized with, for example, a chemical mechanical polishing (CMP) method.

Next, as illustrated in FIG. 8B, the aperture H1 is formed in the insulating film 15. In more detail, a region of the insulating film 15 which opposes the lower electrode 14 is partially and selectively removed with, for example, the dry etching using the photolithography method. As a result, the surface of the lower electrode 14 is exposed above the insulating film 15.

Next, as illustrated in FIG. 9A, the organic photoelectric conversion layer 17G, which is made of the above materials and the like, is formed with, for example, a vacuum deposition method. As a result, the organic photoelectric conversion layer 17G is formed within the aperture H1 while making contact with the lower electrode 14.

Next, as illustrated in FIG. 9B, the upper electrode 18 is formed. In more detail, the above conductive film is formed on the organic photoelectric conversion layer 17 with, for example, the vacuum deposition method or sputtering method, so as to cover the overall surface of the semiconductor substrate 11. In this case, it is desirable for the conductive film to be formed subsequently to the formation of the organic photoelectric conversion layer 17, in a vacuum atmosphere (through the same vacuum processing step). After the conductive film is formed in this manner, the upper electrode 18 is formed by subjecting the conductive film to, for example, patterning using etching in the photolithography method. In this case, the organic photoelectric conversion layer 17G may also be subjected to the patterning at the same time.

Next, as illustrated in FIG. 10, the application film 19, which is made of the above material (e.g. SOG), is formed to a predetermined thickness with an application method such as the spin coat or dip coat method. As a result, the application film 19 is formed in a predetermined curved shape.

Finally, the sealing layer 20 is formed. In more detail, as illustrated in FIG. 11, first, the sealing layer 20, which is made of the above inorganic material, is formed on the application film 19 with, for example, the plasma CVD method. As a result, the lower convex lens portion 20B is formed on the lower surface of the sealing layer 20. As illustrated in FIG. 12, then, the surface of the sealing layer 20 is planarized with, for example, the CMP method. Followed by, the upper convex lens 20A is formed on the upper surface of the sealing layer 20 (the upper surface of the sealing layer 20 is processed into a lens shape). In this case, first, a patterned photoresist 210 is formed on the sealing layer 20 as illustrated in FIG. 13, and then the formed photoresist 210 is subjected to a reflow treatment as illustrated in FIG. 14. After that, the upper surface of the sealing layer 20 is entirely subjected to, for example, etchback using the dry etching, so that the upper convex lens 20A is formed on the upper surface of the sealing layer 20. Through the above processing steps, the photoelectric conversion element 10, as illustrated in FIG. 1, is formed.

### (Function and Effect)

The photoelectric conversion element 10 according to the present embodiment acquires the signal charges in the following manner, for example, as each pixel of a solid-state image pickup device. Specifically, when light enters the photoelectric conversion element 10, the light passes through the upper convex lens 20A and lower convex lens portion 20B of the sealing layer 20. Then, the light is photoelectrically converted for each wavelength, in either of the organic photoelectric conversion section 10a (11G) and the inorganic photoelectric conversion section 10b (the inorganic photoelectric conversion layers 11B and 11R).

In this case, green light is selectively detected by (or absorbed into) the organic photoelectric conversion section 11G, and is photoelectrically converted. In response, out of generated pairs of electron and hole, for example, the electrons are extracted from the lower electrode 14, and then are stored in the green storage layer 110G through the wire layer 13a and the conductive plugs 120a1 and 120a2. Here, the holes are discharged from the upper electrode 18 through a wire layer (not illustrated). Meanwhile, blue light and red light which are contained in the light having passed through the organic photoelectric conversion section 11G are absorbed into the inorganic photoelectric conversion layers 11B and 11R, respectively, in this order, and are photoelectrically converted. In the inorganic photoelectric conversion layer 11B, electrons corresponding to the blue light are stored in the n-type region (n-type photoelectric conversion layer 111n). Likewise, in the inorganic photoelectric conversion layer 11R, the electrons corresponding to the red light are stored in the n-type region (n-type photoelectric conversion layer 112n).

Upon reading operation, the transfer transistors Tr1, Tr2, and Tr3 are turned ON, and the electrons that have been stored in the green storage layer 110G and the n-type photoelectric conversion layers 111n and 112n are transferred to the FD113, FD 114, and FD 116, respectively. As a result, light receiving signals of the corresponding colors are read by the vertical signal line Lsig to be described later, through other pixel transistors (not illustrated). As described above, the structure in which the organic photoelectric conversion section 11G and the inorganic photoelectric conversion layers 11B and 11R are stacked vertically makes it possible to detect red light, green light, and blue light separately from one another without providing color filters, thereby acquiring signal charges of the corresponding colors.

### Comparative Example

FIG. 15 illustrates a configuration of a main part of a photoelectric conversion element (photoelectric conversion element 100) according to a comparative example of the present embodiment. In the photoelectric conversion element 100, the inorganic photoelectric conversion section 10b and the organic photoelectric conversion section 11G are also formed in and above the semiconductor substrate 11, respectively, similar to the photoelectric conversion element 10 of the present embodiment. However, in the photoelectric conversion element 100, a sealing layer 101, a planarized film 102, and an on-chip lens 103 are provided on the organic photoelectric conversion section 11G, in this order. The sealing layer 101 may be made of, for example, an inorganic material, and each of the planarized film 102 and the on-chip lens 103 may be made of, for example, an organic material. In the photoelectric conversion element 100 of the comparative example, as described above, the sealing layer 101 is formed conforming to the shape of the upper surface of the upper electrode 18, and the lower convex lens 20B is not provided, as opposed to the present embodiment. In the comparative example, part of incident light L which is refracted by the on-chip lens 103 is received by the organic photoelectric conversion layer 17G, the inorganic photoelectric conversion sections 11B and 11R. However, the refracted part of the incident light L is not collected properly to, in particular, the inorganic photoelectric conversion sections 11B and 11R which are positioned away from the on-chip lens 103. Consequently, the light collection efficiency is likely to be decreased.

In contrast, in the present embodiment, the lower convex lens portion 20B is provided in addition to the upper convex lens 20A that functions as an on-chip lens, as described above. Accordingly, as illustrated in FIG. 16, the incident light L is refracted by the upper convex lens 20A and the lower convex lens portion 20B, and is collected properly to even the inorganic photoelectric conversion sections 11B and 11R which are positioned away from the on-chip lens 103. Consequently, the light collection efficiency is increased.

Furthermore, in the present embodiment, the lower convex lens portion 20B is provided integrally with the sealing layer 20. With this configuration, damage to the organic photoelectric conversion layer 17G is decreased during manufacturing processing, and the coverage of the sealing layer 20 is enhanced. A reason for this is as follows. In the present embodiment, the application film 19 is provided covering the upper electrode 18, and the upper surface of the application film 19 has a curved shape that is formed so as to substantially trace the uneven shape of the upper electrode 18 (which is caused by the aperture H1 of the insulating film 15), as described above. Therefore, the lower surface of the sealing layer 20 formed on the application film 19 and adjacent thereto also has a curved shape corresponding to that of the application film 19, and this curved shape constitutes the lower convex lens portion 20B.

Examples of a method of forming the lower convex lens as so-called an inner lens include a reflow method and a high density plasma (HDP) sputtering method. When these methods are used, there are cases where a temperature of a formed film exceeds a heatproof temperature (approximately, 100° C. to 200° C.) of an organic photoelectric conversion material. Therefore, those methods may thermally (or physically) damage an organic photoelectric conversion film during manufacturing processing, causing the deterioration of the property thereof. For this reason, the above methods may not be suitable for solid-state image pickup devices including an organic photoelectric conversion film.

In the present embodiment, as described above, the lower convex lens portion 20B is formed by depositing the sealing layer 20 on the application film 19. Therefore, the damage to the organic photoelectric conversion layer 17G is decreased during manufacturing processing. In addition, the sealing layer 20 formed on the curved surface in the above manner is less likely to be seamed or distorted than a case where it is formed on a surface with an angled or warped portion. Thus, the coverage of the sealing layer 20 is enhanced.

In the present embodiment, as described above, the lower convex lens portion 20B is provided on the lower surface of the sealing layer 20 while being formed integrally with the sealing layer 20. With this configuration, the damage to the organic photoelectric conversion layer 17G is decreased during manufacturing processing, and the coverage of the sealing layer 20 is enhanced. Consequently, it is possible to increase the efficiency of collecting light to the organic photoelectric conversion layer 17G while securing the reliability.

### [Modification 1]

In the above-described embodiment, as described above, the description is given regarding the case where the organic photoelectric conversion section 10a (11G) photoelectrically converts the green light, and the inorganic photoelectric conversion section 10b (11B and 11R) photoelectrically converts the blue light and red light. However, there is no limitation on a combination of colors (or the allocation of R, G, and B) for the photoelectric conversion sections. Specifically, the organic photoelectric conversion section 10a may be provided with an organic photoelectric conversion layer that photoelectrically converts blue light (or red light), and the inorganic photoelectric conversion section 10b may be provided with two inorganic photoelectric conversion layers that photoelectrically convert green light and red light (or blue light and green light), respectively.

As illustrated in FIG. 17, for example, an organic photoelectric conversion layer 17R that photoelectrically converts the red light may be provided as the organic photoelectric conversion section 10a (11R), and the inorganic photoelectric conversion section 11B and an inorganic photoelectric conversion section 11G that photoelectrically convert the blue light and green light, respectively, may be provided as the inorganic photoelectric conversion section 10b. The shorter the wavelength, the higher the refractive index becomes. Accordingly, the photoelectric conversion section for a long wavelength (e.g. red light) is provided at a closer location, and the photoelectric conversion sections for a shorter wavelength (e.g. blue or green light) are provided at farther locations, so that the light collection efficiency is increased. As described above, it is desirable that the curvature (focal length or light collection point) of each of the upper convex lens 20A and the lower convex lens portion 20B and the stacking order of the photoelectric conversion sections for the corresponding colors be set by utilizing the relationship between the wavelength and the refractive index.

### [Modification 2]

In a solid-state image pickup device to be described later, pupil correction may be made using one or both of the upper convex lens 20A and the lower convex lens portion 20B. Concretely, an optical axis of either or each of the upper convex lens 20A and the lower convex lens portion 20B is shifted in accordance with the location of the corresponding pixel. Alternatively, a curvature of either or each of the upper convex lens 20A and the lower convex lens portion 20B may be changed in accordance of the location with the corresponding pixel. Moreover, the above configurations may be employed in combination.

### [Modification 3]

As illustrated in FIG. 18, a waveguide structure may be formed as an insulating film (or an insulating film corresponding to the interlayer insulating films 12A and 12B in the above embodiment and the like) provided between the semiconductor substrate 11 and the lower electrode 14. Further, this waveguide structure includes a lower refractive index layer 12C (first refractive index layer) and a higher refractive index layer 12D (second refractive index layer). Concretely, the lower refractive index layer 12C is formed in a region that does not oppose the aperture H1, and the higher refractive index layer 12D is formed in a region that opposes the aperture H1. The lower refractive index layer 12C may be made of an inorganic or organic insulating material, such as SiO₂, SOG, SOD, or a low-K material. Meanwhile, the higher refractive index layer 12D is made of an insulating material that has a higher refractive index than the above material of the lower refractive index layer 12C has. It is more desirable for the higher refractive index layer 12D to be made of a material whose refractive index is equal to or higher than a refractive index (approximately 2.0 in the case of using ITO as the lower electrode 14) of the lower electrode 14. The higher refractive index layer 12D, as described above, may be configured of, for example, a single-layer film made of one of a silicon nitride (e.g. P—SiN film formed with the plasma CVD method), hafnium oxide, aluminum oxide, and tantalum oxide, or a stacked-layer film made of two or more of them. In addition, for the higher refractive index layer 12D, an organic material, a stacked-layer film made of organic and inorganic materials, or a combination thereof may be used. The waveguide structure, as described above, that includes the lower refractive index layer 12C and the higher refractive index layer 12D may be formed through, for example, the following processing steps. Specifically, first, the higher refractive index layer 12D is formed throughout the surface of the semiconductor substrate 11, and then a region of the higher refractive index layer 12D which does not oppose the aperture H1 is selectively removed with, for example, etching using the lithography method. After that, after the lower refractive index layer 12C is formed, the surfaces of the higher refractive index layer 12D and lower refractive index layer 12C are planarized (or polished) with, for example, the CMP method. As a result, the waveguide structure, as configured above, is formed. Alternatively, after the lower refractive index layer 12C may be formed in a predetermined region, the higher refractive index layer 12D may be formed. Then, both the surfaces may be planarized. Examples of the method of forming the lower refractive index layer 12 and the higher refractive index layer 12D may include PE-CVD, HDP-CVD, sputtering, and application methods. However, there is no limitation on this method. Moreover, the planarization processing using the CMP method may be performed as necessary, namely, may not be done necessarily.

In this modification, with the above waveguide structure, incident light L is suppressed from being reflected at interfaces between the lower electrode 14 and the semiconductor substrate 11 (reflected light L₁₀₀ of FIG. 18 is suppressed from being generated). Consequently, the leak of light to neighboring pixels, or some other similar disadvantage is suppressed. In fact, in the case where the higher refractive index layer 12D is made of an insulating material having substantially the same refractive index as the lower electrode 14 has, the reflection of the light is effectively suppressed at the interfaces between the lower electrode 14 and the semiconductor substrate 11. Furthermore, for example, in the case where the semiconductor substrate 11 is made of silicon whose refractive index is approximately 4.0, the reflection of the light at the interfaces between the interlayer insulating film and the semiconductor substrate 11 is also suppressed more effectively than a case where a low refractive index material, such as a silicon oxide, is used for the interlayer insulating film. Moreover, in the case where a high refractive index material is used for the interlayer insulating film, the capacity of the interlayer insulating film is prone to being increased. However, since the refractive index layer 12C is formed in the region that does not oppose the aperture H1, the waveguide structure, as described above, which suppresses the increase in the capacity is achieved.

### [Overall Configuration of Solid-state Image Pickup Device]

FIG. 19 is a functional block diagram illustrating a solid-state image pickup device (solid-state image pickup device 1) in which the photoelectric conversion element described in the above embodiment is used for each pixel. The solid-state image pickup device 1 may serve as a CMOS image sensor, and may include, in addition to a pixel section la as an image pickup area, a circuit section 130 provided with, for example, a row scanning section 131, a lateral selection section 133, a column scanning section 134, and a system control section 132. The circuit section 130 may be provided in a region adjacent to the pixel section 1a, or provided (in a region opposing the pixel section 1a) while being stacked on the pixel section 1a.

The pixel section 1a has a plurality of unit pixels P (each of which corresponds to the photoelectric conversion element 10) arranged, for example, in a two-dimensional and matrix fashion. For example, the unit pixels P in each pixel row are connected to a pixel drive line Lread (concretely, row selection line or reset control line), whereas the unit pixels P in each pixel column are connected to the vertical signal line Lsig. Through each pixel drive line Lread, a drive signal that reads a signal from the corresponding pixel is transmitted. Respective ends of the pixel drive lines Lread are connected to output ends of the row scanning section 131 which correspond to the individual rows.

The row scanning section 131 may be configured of, for example, a shift register or address recorder, and serves as a pixel drive section that drives the pixels P in the pixel section 1a, for example, on a row-by-row basis. When the pixel row is selectively scanned by the row scanning section 131, the pixels in this scanned pixel row output signals. Then, these signals are supplied to the lateral selection section 133 through the corresponding vertical signal lines Lsig. The lateral selection section 133 may be configured of, for example, amplifiers or lateral selection switches provided for the corresponding vertical signal lines Lsig.

The column scanning section 134 may be configured of, for example, a shift register or address recorder, and sequentially drives the lateral selection switches of the lateral selection section 133 while scanning them. In response to the selective scanning of the column scanning section 134, the signals that have been transmitted from the pixels through the vertical signal lines Lsig are sequentially transmitted to lateral signal lines 135, and are output to the exterior through the lateral signal lines 135.

The system control section 132 receives a clock or data instructing an operation mode which is supplied from the exterior, or outputs data, such as internal information regarding the solid-state image pickup device 1. In addition, the system control section 132 includes a timing generator that generates various timing signals, and controls the driving of, for example, the row scanning section 131, the lateral selection section 133, and the column scanning section 134, on the basis of the various timing signals generated by the timing generator.

### [Exemplary Application]

The above solid-state image pickup device 1 is applicable to various types of electronic apparatuses equipped with an image pickup function, including camera systems such as digital still cameras or video cameras, and cellular phones having an image pickup function. FIG. 20 illustrates a general configuration of an electronic apparatus 2 (camera), as an exemplary application. The electronic apparatus 2 serves as a video camera that captures, for example, still or moving images, and includes the solid-state image pickup device 1, an optical system (optical lens) 310, a shutter device 311, a drive section 313 that drives the solid-state image pickup device 1 and the shutter device 311, and a signal processing section 312.

The optical system 310 guides an image light (incident light) from a subject to the pixel section 1a in the solid-state image pickup device 1. The optical system 310 may include, for example, a plurality of optical lenses. The shutter device 311 controls a light irradiation period and light shielding period of the solid-state image pickup device 1. The drive section 313 controls a transmission operation of the solid-state image pickup device 1 and a shutter operation of the shutter device 311. The signal processing section 312 subjects a signal output from the solid-state image pickup device 1 to various signal processes. An image signal Dout obtained as a result of the signal processes is stored in a storage medium such as a memory, or output to, for example, a monitor.

Up to this point, the embodiment, modifications, exemplary application, and the like have been described. However, an embodiment of the present disclosure is not limited to the above embodiment and the like, and various variations thereof may be contemplated. In the above embodiment and the like, for example, the configuration has been exemplified, in which the organic photoelectric conversion section and the inorganic photoelectric conversion section are stacked vertically in the single pixel; however, a pixel configuration of a solid-state image pickup device according to an embodiment of the present disclosure is not limited to the above vertically stacked configuration. For example, another configuration may be employed, in which the organic photoelectric conversion section and the inorganic photoelectric conversion section are arrayed two-dimensionally in the light receiving area, or the organic photoelectric conversion section is provided alone.

In the above embodiment and the like, the description has been given by exemplifying the backside illumination type of solid-state image pickup device; however, an embodiment of the present disclosure is also applicable to a frontside illumination type of solid-state image pickup devices.

It is not necessary for a photoelectric conversion element according to an embodiment of the present disclosure to include all the components that have been described in the above embodiment and the like. Furthermore, a photoelectric conversion element according to an embodiment of the present disclosure may include one or more additional layers.

Furthermore, the technology encompasses any possible combination of some or all of the various embodiments described herein and incorporated herein.

It is possible to achieve at least the following configurations from the above-described example embodiments of the disclosure.

(1) A solid-state image pickup device, including:

a plurality of pixels each including an organic photoelectric conversion layer;

a sealing layer that covers the pixels; and

a first lens section provided for each of the pixels and provided on a side, of the sealing layer, on which the organic photoelectric conversion layer is located, the first lens section being formed integrally with the sealing layer.

(2) The solid-state image pickup device according to (1), wherein

each of the pixels includes, on a semiconductor substrate, in recited order: a first electrode provided for each of the pixels; an insulating film having an aperture; the organic photoelectric conversion layer; a second electrode; and an application film, and

the sealing layer is provided adjacent to the application film.

(3) The solid-state image pickup device according to (2), wherein the first lens section has a curved shape that conforms to a shape of a light incident surface of the application film.
(4) The solid-state image pickup device according to (3), wherein the application film is configured of a material having a lower refractive index than the sealing layer has.
(5) The solid-state image pickup device according to (4), wherein the application film is configured of a material selected from a group consisting of Spin on Glass, Spin on Dielectric, photoresist, polyimide, and polybenzoxazole.
(6) The solid-state image pickup device according to (4) or (5), wherein the sealing layer is a single-layer film or a stacked-layer film, the single-layer film being configured of a material selected from a group consisting of a silicon oxide, a silicon nitride, an aluminum oxide, a hafnium oxide, a tantalum oxide, a zirconium oxide, a titanium oxide, a silicone resin, polyimide, polybenzoxazole, an acrylic resin, and polystyrene, and the stacked-layer film being configured of two or more materials selected from the group.
(7) The solid-state image pickup device according to any one of (1) to (6), further including a second lens section provided for each of the pixels and provided on a light incident side of the sealing layer, and being formed integrally with the sealing layer.
(8) The solid-state image pickup device according to any one of (1) to (7), further including one or more inorganic photoelectric conversion layers provided in a semiconductor substrate,

wherein the organic photoelectric conversion layer is provided on the semiconductor substrate.

(9) The solid-state image pickup device according to (8), wherein the one or more inorganic photoelectric conversion layers has a received light wavelength that is shorter than a received light wavelength of the one or more organic photoelectric conversion layers.
(10) The solid-state image pickup device according to any one of (7) to (9), wherein one or both of the first lens section and the second lens section is used to perform a pupil correction.
(11) The solid-state image pickup device according to any one of (1) to (10), wherein

each of the pixels includes, on a semiconductor substrate, in recited order: an interlayer insulating film; a first electrode provided for each of the pixels; an insulating film having an aperture; the organic photoelectric conversion layer; and a second electrode, and

the interlayer insulating film includes a first refractive index layer and a second refractive index layer, the first refractive index layer being provided in a region unopposed to the aperture of the insulating film, and the second refractive index layer being provided in a region that opposes the aperture of the insulating film, and has a refractive index that is higher than a refractive index of the first refractive index layer.

(12) A method of manufacturing a solid-state image pickup device, the method including:

forming a plurality of pixels each including an organic photoelectric conversion layer; and

forming a sealing layer that covers the pixels, the forming the sealing layer including forming a first lens section provided for each of the pixels and provided on a side, of the sealing layer, on which the organic photoelectric conversion layer is located, the first lens section being formed integrally with the sealing layer.

(13) The method of manufacturing the solid-state image pickup device according to (12), wherein

the forming the plurality of pixels includes forming, on a semiconductor substrate, in recited order: a first electrode provided for each of the pixels; an insulating film having an aperture; the organic photoelectric conversion layer; a second electrode; and an application film, and

in the forming the sealing layer, the sealing layer is formed on the application film and adjacent to the application film.

(14) The method of manufacturing the solid-state image pickup device according to (12) or (13), wherein the forming the sealing layer includes forming a second lens section provided for each of the pixels and provided on a light incident side of the sealing layer, the second lens section being formed integrally with the sealing layer.
(15) The method of manufacturing the solid-state image pickup device according to (14), wherein, in the forming the sealing layer, the sealing layer is deposited on the application film to form the first lens section having a curved surface corresponding to a surface shape of the application film, and a surface of the deposited sealing layer is processed to form the second lens section.
(16) The method of manufacturing the solid-state image pickup device according to any one of (12) to (15), wherein

the forming the plurality of pixels includes forming, on a semiconductor substrate, in recited order: an interlayer insulating film; a first electrode provided for each of the pixels; an insulating film having an aperture; the organic photoelectric conversion layer; and a second electrode, and

the interlayer insulating film includes a first refractive index layer and a second refractive index layer, the first refractive index layer being provided in a region unopposed to the aperture of the insulating film, and the second refractive index layer being provided in a region that opposes the aperture of the insulating film, and has a refractive index that is higher than a refractive index of the first refractive index layer.

(17) An electronic apparatus provided with a solid-state image pickup device, the solid-state image pickup device including:

a plurality of pixels each including an organic photoelectric conversion layer;

a sealing layer that covers the pixels; and

a first lens section provided for each of the pixels and provided on a side, of the sealing layer, on which the organic photoelectric conversion layer is located, the first lens section being formed integrally with the sealing layer.

The present disclosure contains subject matter related to that disclosed in Japanese Priority Patent Applications JP 2012-206569 and JP 2012-258402 filed in the Japan Patent Office on Sep. 20, 2012 and Nov. 27, 2012, respectively, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state image pickup device, comprising:
a plurality of pixels each including an organic photoelectric conversion layer;
a sealing layer that covers the pixels; and
a first lens section provided for each of the pixels and provided on a side, of the sealing layer, on which the organic photoelectric conversion layer is located, the first lens section being formed integrally with the sealing layer.

2. The solid-state image pickup device according to claim 1, wherein
each of the pixels includes, on a semiconductor substrate, in recited order: a first electrode provided for each of the pixels; an insulating film having an aperture; the organic photoelectric conversion layer; a second electrode; and an application film, and
the sealing layer is provided adjacent to the application film.

3. The solid-state image pickup device according to claim 2, wherein the first lens section has a curved shape that conforms to a shape of a light incident surface of the application film.

4. The solid-state image pickup device according to claim 3, wherein the application film is configured of a material having a lower refractive index than the sealing layer has.

5. The solid-state image pickup device according to claim 4, wherein the application film is configured of a material selected from a group consisting of Spin on Glass, Spin on Dielectric, photoresist, polyimide, and polybenzoxazole.

6. The solid-state image pickup device according to claim 4, wherein the sealing layer is a single-layer film or a stacked-layer film, the single-layer film being configured of a material selected from a group consisting of a silicon oxide, a silicon nitride, an aluminum oxide, a hafnium oxide, a tantalum oxide, a zirconium oxide, a titanium oxide, a silicone resin, polyimide, polybenzoxazole, an acrylic resin, and polystyrene, and the stacked-layer film being configured of two or more materials selected from the group.

7. The solid-state image pickup device according to claim 1, further comprising a second lens section provided for each of the pixels and provided on a light incident side of the sealing layer, and being formed integrally with the sealing layer.

8. The solid-state image pickup device according to claim 7, further comprising one or more inorganic photoelectric conversion layers provided in a semiconductor substrate,
wherein the organic photoelectric conversion layer is provided on the semiconductor substrate.

9. The solid-state image pickup device according to claim 8, wherein the one or more inorganic photoelectric conversion layers has a received light wavelength that is shorter than a received light wavelength of the one or more organic photoelectric conversion layers.

10. The solid-state image pickup device according to claim 7, wherein one or both of the first lens section and the second lens section is used to perform a pupil correction.

11. The solid-state image pickup device according to claim 1, wherein
each of the pixels includes, on a semiconductor substrate, in recited order: an interlayer insulating film; a first electrode provided for each of the pixels; an insulating film having an aperture; the organic photoelectric conversion layer; and a second electrode, and
the interlayer insulating film includes a first refractive index layer and a second refractive index layer, the first refractive index layer being provided in a region unopposed to the aperture of the insulating film, and the second refractive index layer being provided in a region that opposes the aperture of the insulating film, and has a refractive index that is higher than a refractive index of the first refractive index layer.

12. A method of manufacturing a solid-state image pickup device, the method comprising:
forming a plurality of pixels each including an organic photoelectric conversion layer; and
forming a sealing layer that covers the pixels, the forming the sealing layer including forming a first lens section provided for each of the pixels and provided on a side, of the sealing layer, on which the organic photoelectric conversion layer is located, the first lens section being formed integrally with the sealing layer.

13. The method of manufacturing the solid-state image pickup device according to claim 12, wherein
the forming the plurality of pixels includes forming, on a semiconductor substrate, in recited order: a first electrode provided for each of the pixels; an insulating film having an aperture; the organic photoelectric conversion layer; a second electrode; and an application film, and
in the forming the sealing layer, the sealing layer is formed on the application film and adjacent to the application film.

14. The method of manufacturing the solid-state image pickup device according to claim 12, wherein the forming the sealing layer includes forming a second lens section provided for each of the pixels and provided on a light incident side of the sealing layer, the second lens section being formed integrally with the sealing layer.

15. The method of manufacturing the solid-state image pickup device according to claim 14, wherein, in the forming the sealing layer, the sealing layer is deposited on the application film to form the first lens section having a curved surface corresponding to a surface shape of the application film, and a surface of the deposited sealing layer is processed to form the second lens section.

16. The method of manufacturing the solid-state image pickup device according to claim 12, wherein
the forming the plurality of pixels includes forming, on a semiconductor substrate, in recited order: an interlayer insulating film; a first electrode provided for each of the pixels; an insulating film having an aperture; the organic photoelectric conversion layer; and a second electrode, and
the interlayer insulating film includes a first refractive index layer and a second refractive index layer, the first refractive index layer being provided in a region unopposed to the aperture of the insulating film, and the second refractive index layer being provided in a region that opposes the aperture of the insulating film, and has a refractive index that is higher than a refractive index of the first refractive index layer.

17. An electronic apparatus provided with a solid-state image pickup device, the solid-state image pickup device comprising:
a plurality of pixels each including an organic photoelectric conversion layer;
a sealing layer that covers the pixels; and
a first lens section provided for each of the pixels and provided on a side, of the sealing layer, on which the organic photoelectric conversion layer is located, the first lens section being formed integrally with the sealing layer.
